(19) United States
(12) Patent Application Publication
(10) Pub. No.: US 2025/0393254 A1
(43) Pub. Date: Dec. 25, 2025

(54) TRANSISTOR DEVICE AND MEMORY

(71) Applicant: INSTITUTE OF MICROELECTRONICS OF THE CHINESE ACADEMY OF SCIENCES, Beijing (CN)

(72) Inventors: Ling LI, Beijing (CN); Ming LIU, Beijing (CN); Di GENG, Beijing (CN); Xinlv DUAN, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,237

(22) PCT Filed: Aug. 24, 2022
(86) PCT No.: PCT/CN2022/114598

§ 371 Date: Sep. 4, 2025

(30) Foreign Application Priority Data
Jun. 10, 2022 (CN) 202210657914.X

(51) Int. Cl. H10D 30/67; H10B 12/00

(52) U.S. Cl. CPC H10D 30/6755; H10B 12/00; H10D 30/6731; H10D 30/6736; H10D 30/6757; H10D 30/6706

(57) ABSTRACT

Disclosed in the present disclosure are a transistor device and a memory. The transistor device comprises: a gate; a semiconductor channel, which surrounds a surface of the gate, wherein the semiconductor channel comprises a multi-layer thin film structure, and the multi-layer thin film structure comprises an indium oxide thin film layer, a gallium oxide thin film layer and a zinc oxide thin film layer; a first source drain, which is disposed at a first end of the semiconductor channel; and a second source drain, which is disposed at a second end of the semiconductor channel. By means of the present disclosure, the control ability of the turn-off of the semiconductor channel and the mobility of the semiconductor channel can be adjusted and balanced.

### CROSS-REFERENCE TO RELATED PATENT APPLICATIONS

This application claims a priority from the Chinese Patent Application No. 202210657914.X, filed with the Chinese Patent Office on Jun. 10, 2022, entitled “TRANSISTOR DEVICE AND MEMORY”, contents of which are incorporated herein by reference in its entirety.

### FIELD OF THE INVENTION

The invention relates to the technical field of semiconductor, and in particular to a transistor device and a memory.

### BACKGROUND OF THE INVENTION

Indium Gallium Zinc Oxide (IGZO) is a new type of semiconductor material due to it has higher electron mobility than amorphous silicon (a-Si), as well as a larger switching ratio and lower leakage current, which results in reduced power consumption when the device unit is not in operation and is advantageous in reducing overall product power consumption. However, when IGZO material is currently applied as a semiconductor channel in a memory, there are still contradictory issues of lower operating current or difficulty in turning off, i.e., increasing device operating current tends to suffer from difficulty in turning off, and increasing turn off control ability tends to result in lower operating current.

Therefore, how to better balance the operating current of a transistor device and the turn-off control ability of a semiconductor channel becomes a problem that is currently urgently addressed.

### SUMMARY OF THE INVENTION

In view of the above problems, the present disclosure presents a transistor device and a memory that enables adjusting and balancing of the turn-off control ability of a semiconductor channel and a mobility of the semiconductor channel.

In a first aspect of the present disclosure, there is provided a transistor device comprising: a gate; a semiconductor channel, which surrounds a surface of the gate and includes a multi-layer thin film structure, in which the multi-layer thin film structure includes an indium oxide thin film layer, a gallium oxide thin film layer, and a zinc oxide thin film layer; a first source drain disposed at a first end of the semiconductor channel; and a second source drain disposed at a second end of the semiconductor channel.

In a second aspect of the present disclosure, there is provided a memory comprising the transistor devices as described in the preceding first aspect.

A transistor device and a memory are provided in one or more embodiments of the disclosure, in which the transistor device includes: a gate; a semiconductor channel, which surrounds a surface of the gate and includes a multi-layer thin film structure, in which the multi-layer thin film structure includes an indium oxide thin film layer, a gallium oxide thin film layer, and a zinc oxide thin film layer; a first source drain disposed at a first end of the semiconductor channel; and a second source drain disposed at a second end of the semiconductor channel. One or more embodiments of the present disclosure provide for adjusting and balancing the turn-off control ability of the semiconductor channel and the mobility of the semiconductor channel by accurately controlling the ratio of each element of indium, gallium, and zinc during fabrication through layered structure design.

The foregoing description is merely a summary of the technical solutions of the present disclosure, in order that the technical means of the present disclosure can be more clearly understood, and may be practiced in light of the description, and in order that the above and other objects, features and advantages of the present disclosure can be more clearly understood. The following sets forth specific embodiments of the present disclosure.

### BRIEF DESCRIPTION OF THE DRAWINGS

In order to more clearly illustrate technical solutions in embodiments of the present disclosure, the accompanying drawings used in the description of the embodiments will now be briefly described. It will be apparent that the drawings in the following description are some embodiments of the present disclosure and that other drawings can be derived from these drawings without inventive step for a person of ordinary skill in the art.

FIGS. 1, 3, 4, and 8 respectively show structural diagrams of different implementations of a transistor device in accordance with one or more embodiments of the disclosure;

FIG. 2 shows a structural diagram of a semiconductor channel of a transistor device in accordance with one or more embodiments of the disclosure;

FIG. 5 shows a gate location structural diagram of a transistor device in accordance with one or more embodiments of the disclosure;

FIGS. 6 and 7 respectively show second end electric field distribution schematics of gates of different transistor devices in accordance with one or more embodiments of the disclosure; and

FIG. 9 shows a structural diagram of a 2T0C device structure composed of a transistor device in accordance with one or more embodiments of the disclosure.

### DETAILED DESCRIPTION OF THE INVENTION

Embodiments of the present disclosure will be described below with reference to the drawings. Nevertheless, it will be understood that the description is by way of example only and is not intended to limit the scope of the disclosure. Further, in the following description, descriptions of well-known structures and techniques are omitted in order to avoid unnecessarily obscuring the concepts of the present disclosure.

Various structural diagrams according to embodiments of the present disclosure are shown in the drawings. The figures are not to scale, in which certain details have been exaggerated and may have been omitted for clarity of presentation. The shapes of the various regions, layers and the relative sizes, positional relationships between them shown in the figures are merely exemplary, deviations may in practice be due to manufacturing tolerances or technical limitations, and those skilled in the art may additionally design regions/layers with different shapes, sizes, relative positions according to practical needs.

In the context of the present disclosure, when a layer/component is referred to as being “on” another layer/component, it can be directly on that another layer/element, or an intervening layer/element may be present there between. Additionally, if a layer/component is positioned “on” another layer/component in one orientation, the layer/component may be positioned “under” that another layer/component when the orientation is reversed.

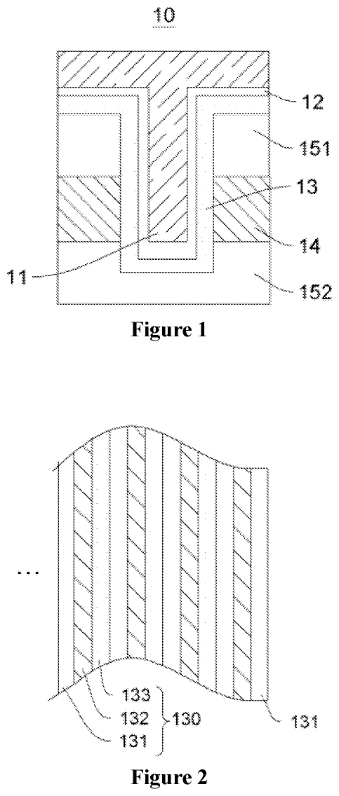

Referring to FIG. 1, a transistor device 10 is provided in this embodiment comprising a gate 11, a gate insulating layer 12, a semiconductor channel 13, an electrode insulating layer 14, a first source drain 151, and a second source drain 152.

The gate 11, may be provided as a columnar structure, which may differ in diameter at both ends of the columnar structure. The cross section of the gate 11 perpendicular to the length direction may be circular, elliptical, square, or the other shapes without limitation. For example, a non-circular shape may be employed in some implementations, which may guarantee a larger surface area, improving the control performance of the gate 11. Additionally, due to process cost, the gate 11 with a circular cross-section or the gate 11 with an oval or the like closer than a circular cross-section may be used to achieve better gate control performance, avoiding increased manufacturing costs. The gate 11 may be formed using ITO, IZO, TiN, etc., which may have better conductive properties, and may additionally be formed using a metal or other highly conductive oxide that facilitates growth by an ALD (Atomic layer deposition) process.

In some implementations, the transistor device 10 may further include a substrate. The gate 11, the gate insulating layer 12, the semiconductor channel 13, etc., are all disposed on a same side of the substrate. The length direction of the gate 11 may be perpendicular to the substrate, or approximately perpendicular to the substrate. Having the entire transistor device 10 as a vertical structure facilitates higher density large scale stacking. The substrate material may employ commonly used substrate materials, such as Si, SiO₂, SiC, etc., and even other flexible substrate materials, without limitation.

The gate insulating layer 12 is disposed around the side of the gate 11. In some implementations, the gate insulating layer 12 may wrap around the surface of the gate 11, enabling insulating isolation between the semiconductor channel 13 and the gate 11. The gate insulating layer 12 can be implemented using HfO, HfAlO, Al₂O₃, or the like. Although the gate insulating layer 12 can be made by combining multiple thin films of different materials, without limitation. When the first end of the semiconductor channel 13 is the end away from the substrate, in some implementations, the gate insulating layer 12 may completely wrap the second end of the gate 11, advantageously improving the control performance of the gate 11 on the semiconductor channel 13. It is also possible to wrap around only on the surface of the second end of the gate 11 (not wrapping around the end face), facilitating underwiring of the gate 11.

The semiconductor channel 13 surrounds the surface of the gate 11. In some implementations, it may wrap around the side of the gate insulating layer 12 away from the gate 11. This structure results in a CAA (Channel-All-Around) structure between the semiconductor channel 13 and the gate 11. That is, the semiconductor channel 13 wraps around outside the gate 11, which effectively increases the area of the semiconductor channel 13, boosts the carrier count of the semiconductor channel 13, and increases the current conduction efficiency. At the same time, since the semiconductor channel 13 is wrapped all around outside the gate 11, the area of the semiconductor channel 13 corresponding to the gate 11 is effectively increased, thereby improving the control performance of the semiconductor channel 13 by the gate 11. This design structure, which increases the area of control of the gate 11 over the semiconductor channel 13, and the area of the semiconductor channel 13 at a limited volume, allows for smaller micro-constrictions.

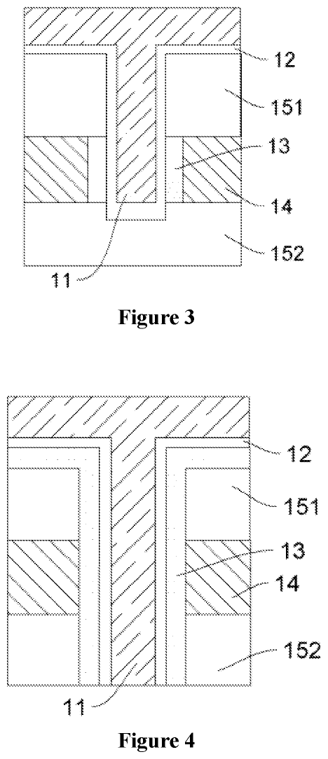

In some implementations, the semiconductor channel 13 in this embodiment can be implemented with IGZO material. Referring to FIG. 2, in some implementations, the semiconductor channel 13 includes a multi-layer thin film structure. The multi-layer thin film structure includes an indium oxide thin film layer 131, gallium oxide thin film layer 132, and zinc oxide thin film layer 133. Specifically, the multi-layer thin film structure may be formed by alternately stacking the indium oxide thin film layer 131, the gallium oxide thin film layer 132, and the zinc oxide thin film layer 133. The order of the alternating layers is not limited. The semiconductor channel 13 with a high proportion of indium can reach a larger on-state current at the same gate voltage, but the threshold voltage of the device is more negative. That is, the threshold voltage of the device is less than 0 V and is more distant from 0 V. The transistor threshold voltage of the semiconductor channel 13 with a low proportion of indium is more positive. That is, the threshold voltage of the device is greater than 0 V, or less than 0 V but closer to 0 V, but the device on-state current will be less. It is noted that depending on the requirements for the expected performance of the device, the reference that is used to judge whether it is close to positive or negative may vary. For example, −1 V may be taken as a reference, with greater than −1 V being close to positive and less than −1 V being close to negative.

Thus, the ratio of each element of indium, gallium, and zinc can be accurately controlled during fabrication by the layered structure design in this embodiment, thereby enabling adjusting and balancing of the turn-off control ability of the semiconductor channel 13 and the mobility of the semiconductor channel 13.

In some implementations, the multi-layer thin film structure includes a plurality of unit structure layers stacked in sequence. Each unit structure layer 130 includes an indium oxide thin film layer 131, a gallium oxide thin film layer 132, and a zinc oxide thin film layer 133. With this structure, cyclic stacking of the indium oxide thin film layer 131, the gallium oxide thin film layer 132, and the zinc oxide thin film layer 133 is achieved, which effectively improves carrier uniformity within the semiconductor channel 13, ensuring better mobility.

In some implementations, the unit structure layer 130 is sequentially stacked from a direction away from the gate 11 to a direction closer to the gate 11 by an indium oxide thin film layer 131, a gallium oxide thin film layer 132, and a zinc oxide thin film layer 133. It may also be stacked by a zinc oxide thin film layer 133, an indium oxide thin film layer 131, and a gallium oxide thin film layer 132. It may also be stacked by a gallium oxide thin film layer 132, an indium oxide thin film layer 131, and a zinc oxide thin film layer 133, or by a gallium oxide thin film layer 132, a zinc oxide thin film layer 133, and an indium oxide thin film layer 131. Such a stacked structure may ensure that the indium oxide thin film layer 131 and the gallium oxide thin film layer 132 are adjacent to each other, thereby effectively suppressing formation of oxygen vacancies and improving device control ability.

In some implementations, the proportion of indium oxide material in the unit structure layer 130 is ⅗ to ¾, which can achieve greater on-state current at the same gate voltage condition of the transistor device 10. Optionally, the same ratio of the gallium oxide material as that of zinc oxide material in the unit structure layer 130 may be provided, which guarantees better turn-off performance of the gate 11 to the semiconductor channel 13 while guaranteeing that a large on-state current is reached, achieving a balance between high current and easy turn-off of the semiconductor channel 13. That is, in some possible implementations, the ratio of InOₓ:GaOₓ:ZnOₓ may be ranged from 3:1:1 to 6:1:1, e.g., 5:1:1.

In some implementations, the thickness of each of the indium oxide thin film layer 131, the gallium oxide thin film layer 132, and the zinc oxide thin film layer 133 in this embodiment is less than 1 Angstrom. Thus, even if the compounds of different layers are alternately deposited, the finally formed multi-element semiconductor thin film is not seen as a layered structure and can still be equivalently considered as a complete mixture of these several elements, guaranteeing the other properties of the IGZO material.

In some implementations, the semiconductor channel 13 further includes an outer thin film layer. The outer thin film layer is disposed on the surface of the multi-layer thin film structure closest to the gate 11. The material of the outer thin film layer is indium oxide. That is, an additional layer of indium oxide may be deposited after the last unit structure layer 130 is deposited, resulting in better interface characteristics and improved sub-threshold characteristics and operating current of the device. For example, if the material of the thin film of the unit structure layer 130 closest to the gate 11 is ZnOₓ, an additional layer of InOₓ is provided on the ZnOₓ to obtain better interface properties.

In some implementations, the thickness of the semiconductor channel 13 is 3 nm to 5 nm, thereby ensuring better mobility of the semiconductor channel 13, while also facilitating microscopic and high-density large-scale arrays of the entire transistor device 10.

The first source drain 151 is disposed at the first end of the semiconductor channel 13 and is connected with the semiconductor channel 13. The second source drain 152 is disposed at the second end of the semiconductor channel 13 and is connected with the semiconductor channel 13. The first end of the semiconductor channel 13 is the end away from the substrate, and the second end of the semiconductor channel 13 can be the end near the substrate. The electrode insulating layer 14 is disposed around the side of the semiconductor channel 13 away from the gate 11, and between the first source drain 151 and the second source drain 152. The electrode insulating layer 14 serves to isolate the first source drain 151 and the second source drain 152 from short circuit between the first source drain 151 and the second source drain 152.

In some implementations, the first source drain 151 may be disposed around the side of the gate insulating layer 12 away from the gate 11, and is connected with the first end of the semiconductor channel 13. The second source drain 152 can be disposed around a side of the gate insulating layer 12 away from the gate 11, and is connected with the second end of the semiconductor channel 13, as shown in FIG. 3. In other implementations, the first source drain 151 may be disposed around the side of the semiconductor channel 13 away from the gate 11, and the second source drain 152 may be disposed around the side of the semiconductor channel 13 away from the gate 11, as shown in FIG. 4. Such an implementation may enable a larger contact area to be formed between the source drain and the semiconductor channel 13. The conduction efficiency of the carriers is favored.

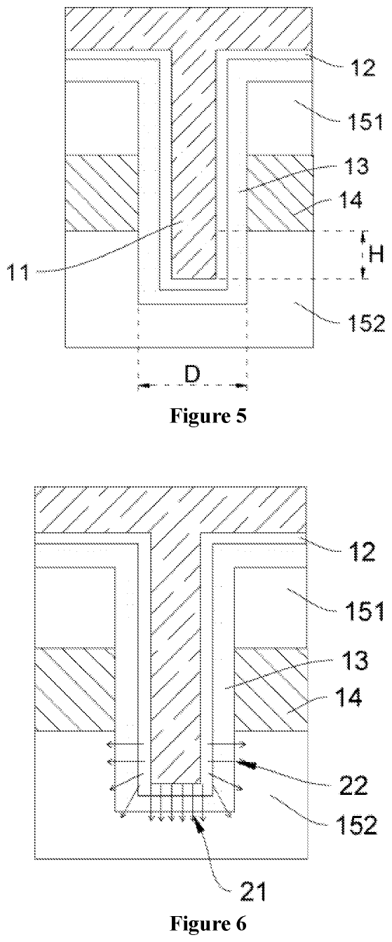

In some implementations, the second source drain 152 is disposed wrapped around the second end of the semiconductor channel 13. That is, the second source drain 152 wraps the gate insulating layer 12 at the second end of the semiconductor channel 13. The second end of the semiconductor channel 13 and the second end of the gate 11 extend into the second source drain 152, as shown in FIG. 5. With the gate 11 and the semiconductor channel 13 extending deeply into the second source drain 152, the contact area between the semiconductor channel 13 and the second source drain 152 may be larger.

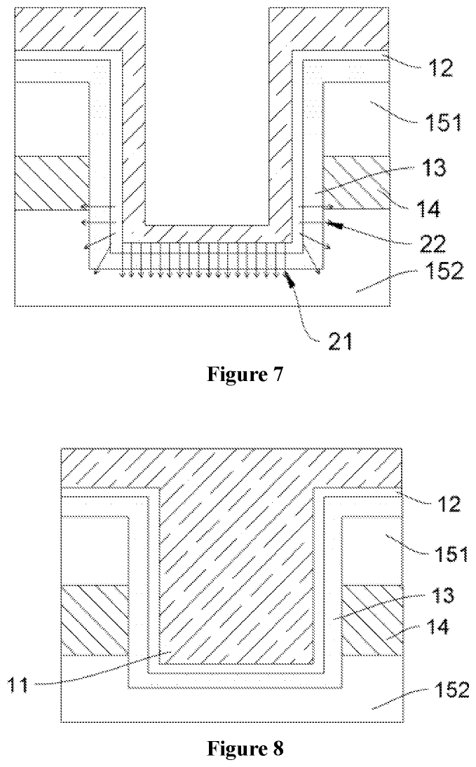

Referring to FIG. 6, since the gate 11 also extends into the second source drain 152, the second end of the gate 11 may form an electric field (for convenience, referred to as a first electric field herein after) in a direction away from the first end of the gate 11, and an electric field (for convenience, referred to as a second electric field herein after) can be formed in a direction to sides of semiconductor channel 13, which are the two directions where the semiconductor channel 13 is connected with the source drain. Thus, the structure in which the gate 11 and the semiconductor channel 13 extend into the second source drain 152, can further enhance the control ability of the gate 11 over the contact location on the semiconductor channel 13 with the second source drain 152, thereby improving the performance of the overall device and avoiding generation of leakage current.

In order to guarantee the control ability of the second end of the gate 11 over the semiconductor channel 13, the length of the gate 11 extending into the second source drain 152 may be set to be no less than 10 nm, so that there is a sufficient width of the second electric field to guarantee a better control performance over the semiconductor channel 13 contacted by the second source drain 152. At this time, the peripheral diameter of the semiconductor channel 13 extending into the end of the second source drain 152 can be controlled to be less than 50 nm, enabling device microscaling. Of course, in some implementations, the peripheral diameter of the second end of the semiconductor channel 13 can also be set larger, so that the first electric field generated by the gate 11 can cover the second source drain 152 more efficiently, and the gate 11 can make a control more efficiently, as shown in FIGS. 7 and 8. In addition, the control ability of the gate 11 to the second end of the semiconductor channel 13 is mainly determined by the first electric field. Therefore, the length of the gate 11 extending into the second source drain 152 may not be limited to less than 10 nm.

In some implementations, if the semiconductor channel 13 with a larger peripheral diameter is employed, it will be difficult to reduce the volume of the device. Thus, in order to guarantee a good control performance of the second end of the gate 11 to the second end of the semiconductor channel 13, the peripheral diameter of the end of the semiconductor channel 13 extending into the second source drain 152 and the length of the gate 11 extending into the second source drain 152 may be controlled to satisfy the relationship H≥0.5×(120 nm−D), where H is the length of the gate 11 extending into the second source drain 152, D is the peripheral diameter of the end of the semiconductor channel 13 extending into the second source drain 152, and it may be controlled to satisfy D<100 nm at this time. Thus, a balance between the first electric field and the second electric field is achieved, which guarantees the control performance of the gate 11 to the second end of the semiconductor channel 13 while facilitating a further microscopic and miniaturization of the device, as shown in FIG. 5. Moreover, when the semiconductor channel 13 extends into the second source drain 152 without penetrating, both the end surface and the side surface of the end of the semiconductor channel 13 near the second source drain 152 can make good contact with the second source drain 152, effectively reducing contact resistance. In addition, when the diameter of the second end of the semiconductor channel 13 is designed to be larger, the contact area of the semiconductor channel 13 with the second source drain 152 can be further increased, reducing contact resistance.

In some implementations, the second source drain 152 may wrap around a surface of the semiconductor channel 13 away from the gate 11, and be located at the second end of the semiconductor channel 13. Such a structure may facilitate etching of the second source drain 152 to penetration during fabrication, thereby depositing the semiconductor channel 13, the gate insulating layer 12, and the gate 11 within a hole, free from control of the etch thickness of the second source drain 152.

The first source drain 151 and the second source drain 152 may be formed using TiN, W, Mo, or the like, which may have better work functions for IGZO materials and better oxidation resistance properties.

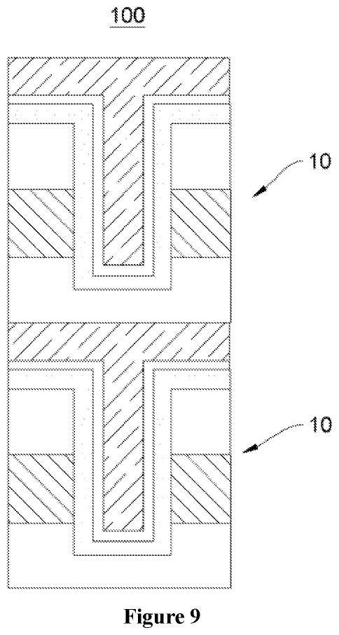

It is also noted that a 2T0C device structure can be conveniently formed with a small footprint since the gate 11 of the transistor device 10 in this embodiment penetrates upward and the second source drain 152 is located below, as shown in FIG. 9. The gate 11 of one transistor device is connected with the second source drain 152 of another transistor device.

In summary, according to one or more embodiments of the disclosure, there is provided a transistor device comprising: a gate; a semiconductor channel, which surrounds a surface of the gate and includes a multi-layer thin film structure, in which the multi-layer thin film structure includes an indium oxide thin film layer, a gallium oxide thin film layer, and a zinc oxide thin film layer; a first source drain disposed at a first end of the semiconductor channel; and a second source drain disposed at a second end of the semiconductor channel. One or more embodiments of the present disclosure provide for adjusting and balancing the turn-off control ability of the semiconductor channel and the mobility of the semiconductor channel by accurately controlling the ratio of each element of indium, gallium, and zinc during fabrication through layered structure design.

Based on the same inventive concept, a memory is also provided in yet another embodiment of the disclosure, comprising the transistor device according to any of the previous embodiments.

It is to be noted that embodiments of the present disclosure provide a memory that employs the transistor device of the foregoing embodiments, and thus provide advantageous effects with reference to those described in the foregoing embodiments, which are not repeated. Additionally, the particular process implementation when the transistor device and each structure in the memory is fabricated may employ existing process technologies, which are not limited in this embodiment.

In the above description, technical details of patterning, etching, and the like of various layer are not described in detail. However, it will be appreciated by those skilled in the art that layers, regions, etc. of the desired shape may be formed by various technical means. In addition, those skilled in the art can also devise processes that are not exactly the same as those described above in order to form the same structure. Additionally, although the various embodiments are described separately above, this does not mean that measures in the various embodiments cannot be advantageously used in combination.

While the preferred embodiments of the present disclosure have been described, further variations and modifications of these embodiments may be effected therein by those skilled in the art once the basic inventive concepts have come to mind. It is therefore intended that the appended claims be construed to include the preferred embodiments along with all changes and modifications that fall within the scope of the disclosure.

It will be apparent to those skilled in the art that various modifications and variations can be made to the present disclosure without departing from the spirit and scope of the disclosure. Thus, it is intended that the present disclosure include such modifications and variations provided they come within the scope of the present claims and their equivalents.

1. A transistor device comprising:
a gate;
a semiconductor channel, which surrounds a surface of the gate and comprises a multi-layer thin film structure, wherein the multi-layer thin film structure comprises an indium oxide thin film layer, a gallium oxide thin film layer, and a zinc oxide thin film layer;
a first source drain disposed at a first end of the semiconductor channel; and
a second source drain disposed at a second end of the semiconductor channel.

2. The transistor device according to claim 1, wherein the multi-layer thin film structure comprises a plurality of unit structure layers stacked in sequence, and each of the unit structure layers comprises the indium oxide thin film layer, the gallium oxide thin film layer, and the zinc oxide thin film layer.

3. The transistor device according to claim 2, wherein the film layer in the unit structure layer is sequentially stacked from a direction away from the gate to a direction closer to the gate by the indium oxide thin film layer, the gallium oxide thin film layer, and the zinc oxide thin film layer.

4. The transistor device according to claim 2, wherein the proportion of indium oxide material in the unit structure layer is ⅗ to ¾.

5. The transistor device according to claim 2, wherein, in the unit structure layer, the proportion of gallium oxide material is the same as that of zinc oxide material.

6. The transistor device according to claim 2, wherein a thickness of each of the indium oxide thin film layer, the gallium oxide thin film layer, and the zinc oxide thin film layer is less than 1 Angstrom.

7. The transistor device according to claim 1, wherein the semiconductor channel further comprises an outer thin film layer, wherein the outer thin film layer is disposed on a surface of the multi-layer thin film structure closest to the gate, and the material of the outer thin film layer is indium oxide.

8. The transistor device according to claim 1, wherein a thickness of the semiconductor channel ranges from 3 nm to 5 nm.

9. The transistor device according to claim 1, wherein the first source drain is disposed around a side of the semiconductor channel away from the gate, and the second source drain is disposed on a side of the semiconductor channel away from the gate.

10. A memory comprising the transistor device according to claim 1.
